(19) United States
(12) Patent Application Publication
(10) Pub. No.: US 2016/0211209 A1
(43) Pub. Date: Jul. 21, 2016

(54) SEMICONDUCTOR STRUCTURE AND METHOD FOR FABRICATING THE SAME

(71) Applicant: Powerchip Technology Corporation, Hsinchu (TW)

(72) Inventors: Hsin-Min Wu, Hsinchu City (TW); Chien-Lung Chu, Hsinchu City (TW); Chun-Hung Chen, Hsinchu County (TW); Ta-Chien Chiu, Miaoli County (TW)

(21) Appl. No.: 14/672,238

(22) Filed: Mar. 30, 2015

(30) Foreign Application Priority Data
Jan. 15, 2015 (TW) 104101333

(51) Int. Cl. H01L 23/528; H01L 21/02; H01L 29/06

(52) U.S. Cl. CPC H01L 23/528; H01L 29/0657; H01L 21/02587; H01L 21/02664; H01L 21/02318; H01L 21/022

(57) ABSTRACT

A semiconductor structure and a method for fabricating the semiconductor structure are provided. The semiconductor structure includes a substrate, a plurality of composite layers, and at least one composite pillar. The substrate includes a first region and a second region. The composite layers are disposed on the substrate. Each of the composite layers includes at least one exposed surface and at least one sidewall. At least one staircase structure is formed by the exposed surface and the sidewall. The composite pillar is disposed on the exposed surface of the substrate.

### CROSS-REFERENCE TO RELATED APPLICATION

This application claims the priority benefit of Taiwan application serial no. 104101333, filed on Jan. 15, 2015. The entirety of the above-mentioned patent application is hereby incorporated by reference herein and made a part of this specification.

### BACKGROUND OF THE INVENTION

1. Field of the Invention

The invention generally relates to a semiconductor structure and a method for fabricating the same, and more particularly, to a semiconductor structure having a staircase structure and a method for fabricating the same.

2. Description of Related Art

With the improvement in integrity of integrated circuits, the critical dimension (CD) of semiconductor devices continues to decrease. In order to achieve high density and high performance, developments towards three-dimensional space have become the trend under the condition of having a limited unit area. Using a non-volatile memory as an example, it includes a vertical memory array formed by a plurality of memory cells. Even though the three-dimensional semiconductor device enables memory capacity per unit area to increase, but also raises the difficulty for elements in different layers to connect with each other.

In recent year, staircase semiconductor structures have been developed in the three-dimensional semiconductor device, so as to enable components disposed at each layer to be easily connected with other components. However, defining multilayer staircases requires to undergo multiple times of lithography and etching process, thus not only increasing the production costs but also seriously affects the productivity. In addition, due to component size reduction, difficulty of overlay alignment in a lithography process also increases. Therefore, how to simplify the fabrication process of the staircase structure in the three-dimensional semiconductor device, as well as increasing a process margin of the lithography process, is a current topic that needs to be researched.

### SUMMARY OF THE INVENTION

The invention is directed to a semiconductor structure capable of increasing a process margin of lithography process.

The invention is directed to a method for fabricating the semiconductor structure that is capable of greatly reducing the number of photomasks and the process steps being required.

The invention is directed to a semiconductor structure, which includes a substrate, a plurality of composite layers and at least one composite pillar. The substrate includes a first region and a second region. The composite layers are disposed on the substrate. Each of the composite layers includes at least one exposed surface and at least one sidewall. The exposed surfaces and the sidewalls form at least one staircase structure. The composite pillar is disposed on the exposed surface of one of the composite layers.

In one embodiment of the invention, a height of the composite pillar is greater than or equal to a height of the composite layers.

In one embodiment of the invention, the composite layers are N layers, and the number of the composite pillars is X, wherein X≦N/2−1, N≧4 and N is an even number, and X≧1 and X is an integer.

In one embodiment of the invention, the staircase structures are respectively disposed at the first region and the second region of the substrate, and heights of the staircase structures decrease respectively along opposite directions.

In one embodiment of the invention, the composite pillar is disposed on the exposed surface of the composite layer at the first region or the second region of the substrate.

In one embodiment of the invention, a sidewall of the composite pillar is connected with one of the sidewalls of the composite layer.

In one embodiment of the invention, each of the composite layers at least includes two material layers, and the material layers include conductor layers, semiconductor layers, dielectric layers, or a combination thereof.

The invention is directed to a method for fabricating the semiconductor structure that includes the following steps. A substrate is provided, and the substrate includes a first region and a second region. A plurality of composite layers is formed on the substrate. The patterning process is performed to the composite layers for m times, in which m is a positive integer greater than 1, so as to form at least one staircase structure and at least one composite pillar on the substrate. Wherein, performing the patterning process for m 2 times includes the following steps. A m^{th} patterned mask layer is formed, the m^{th} patterned mask layer covers a sidewall of at least one (m−1)^{th} trench formed by the (m−1)^{th} time of the patterning process. Through using the m^{th} patterned mask layer as a mask, parts of the composite layers are removed to form at least one m^{th} trench. The m^{th} patterned mask layer is removed. Moreover, the staircase structure includes at least one exposed surface, and the composite pillar is disposed on the exposed surface of the staircase structure.

In one embodiment of the invention, the composite layers are N layers, N≧4 and N is an even number. When performing the patterning process to the composite layers for m times, a number L of the composite layers being removed satisfies: L=N/2^{m}, until L=1.

In one embodiment of the invention, the method for performing the patterning process to the composite layers for m times includes the following steps. A 1^{st} patterned mask layer covering parts of the composite layers is formed on the substrate. Parts of the composite layers exposed by the 1^{st} patterned mask layer are removed, so as to form a 1^{st} trench. The 1^{st} patterned mask layer is removed. A 2^{nd} patterned mask layer on the substrate covering a sidewall of the 1^{st} trench is formed on the substrate. Parts of the composite layers exposed by the 2^{nd} patterned mask layer are removed, so as to form at least one 2^{nd} trench. The 2^{nd} patterned mask layer is removed, so as to form the at least one staircase structure and the at least one composite pillar on the substrate.

In one embodiment of the invention, the composite layers have a top-most surface, and the 2^{nd} patterned mask layer simultaneously covers the sidewall of the 1^{st} trench and parts of the top-most surface disposed above the sidewall of the 1^{st} trench.

In one embodiment of the invention, a sidewall of the at least one composite pillar includes a portion of the sidewall of the at least one (m−1)^{th} trench or a portion of a sidewall of the at least one m^{th} trench.

In one embodiment of the invention, the method for forming the at least one staircase structure on the substrate includes respectively forming the at least one staircase structure on the first region and the second region of the substrate, and heights of the staircase structures decrease respectively along opposite directions.

In one embodiment of the invention, the method for fabricating the semiconductor structure further includes respectively forming the at least one composite pillar on the first region and the second region of the substrate.

In one embodiment of the invention, a height of the at least one composite pillar is greater than or equal to a height of each of the composite layers.

In one embodiment of the invention, the composite layers are N layers, and the number of the at least one composite pillar is X, wherein X≦N/2−1, N≧4 and N is an even number, and X≧1 and X is an integer.

In view of the above, since the semiconductor structure provided by the invention has the staircase structure and the composite pillar, in addition to enabling components disposed at each layer to connect with other components easily, it may further provide a process margin of an overlay alignment in the lithography process of forming the staircase structure. Moreover, in the method for fabricating the semiconductor structure of the invention, by covering the patterned mask layers on the sidewalls of the trenches and the surfaces of the composite layers, it is facilitative in simultaneously forming the staircase structures and the composite pillars during the subsequent processes. In addition, the number of the composite layers being removed during each time of the patterning process is half of the previous time. Consequently, as compared to the conventional fabrication process, when fabricating staircase structures with same number of layers, the number of times for performing the patterning process can be greatly reduced, thereby achieving goals of lowering the manufacturing costs and enhancing the productivity.

In order to make the aforementioned features and advantages of the present invention more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1H are cross-sectional diagrams illustrating fabrication flows of a semiconductor structure according to an embodiment of the invention.

FIG. 2A to FIG. 2E are cross-sectional diagrams illustrating fabrication flows of a semiconductor structure according to another embodiment of the invention.

FIG. 3 to FIG. 4 are cross-sectional diagrams respectively illustrating a semiconductor structure according to yet another embodiment of the invention.

FIG. 5 to FIG. 12 are cross-sectional diagrams respectively illustrating a semiconductor structure according to still another embodiment of the invention.

### DESCRIPTION OF THE EMBODIMENTS

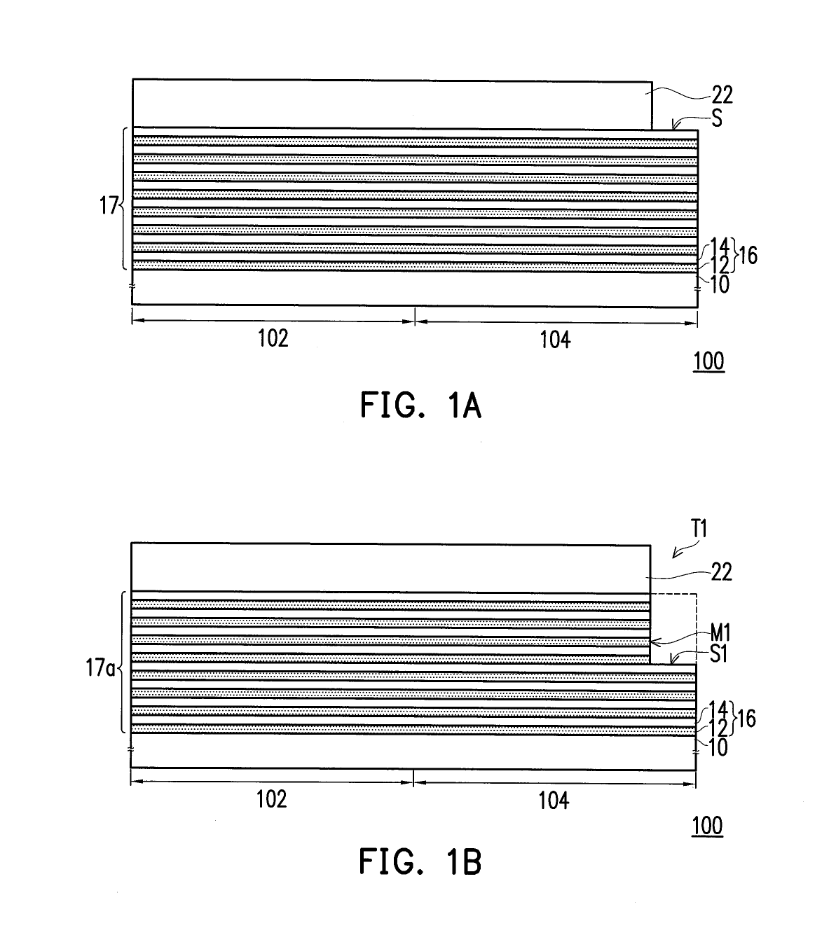

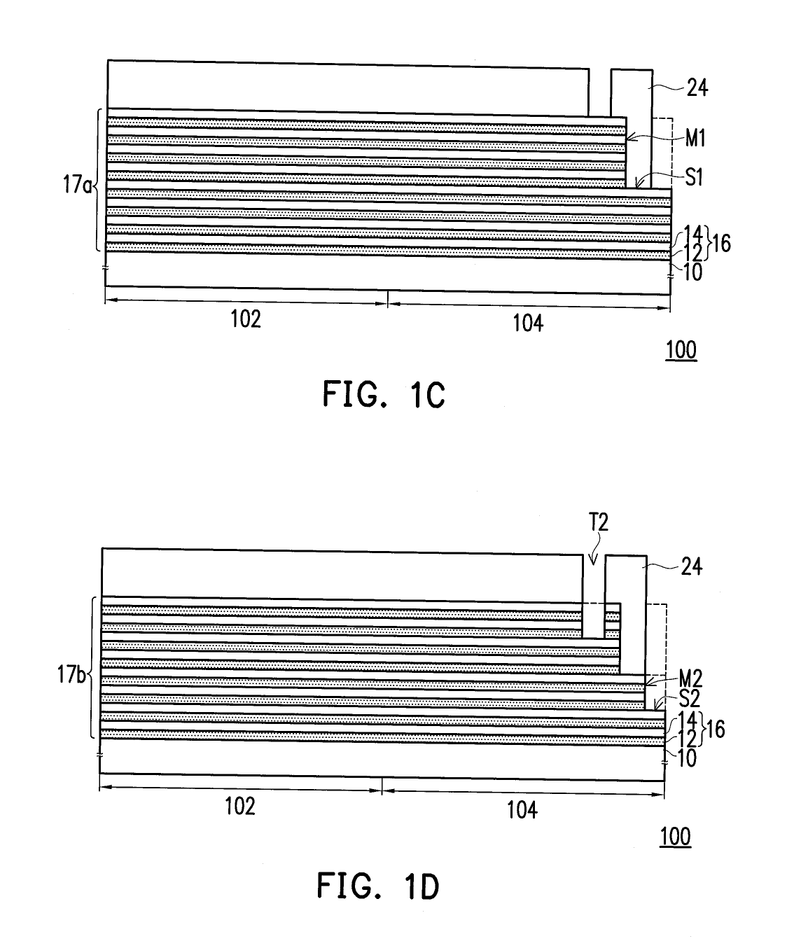

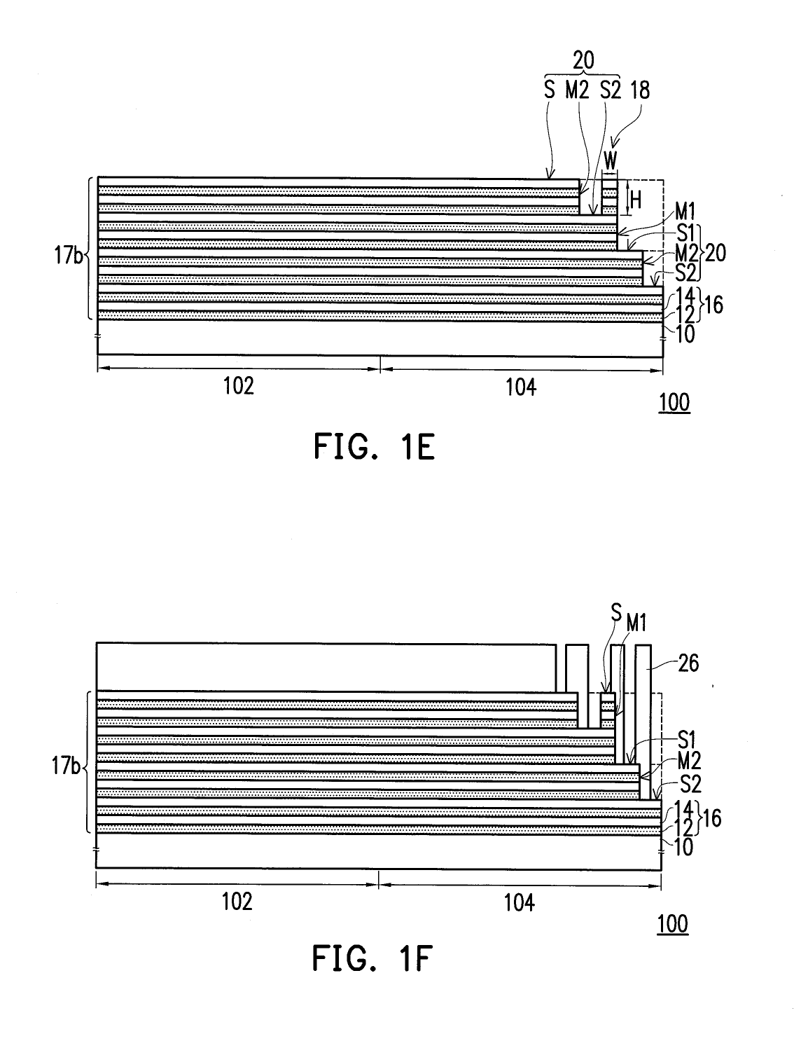

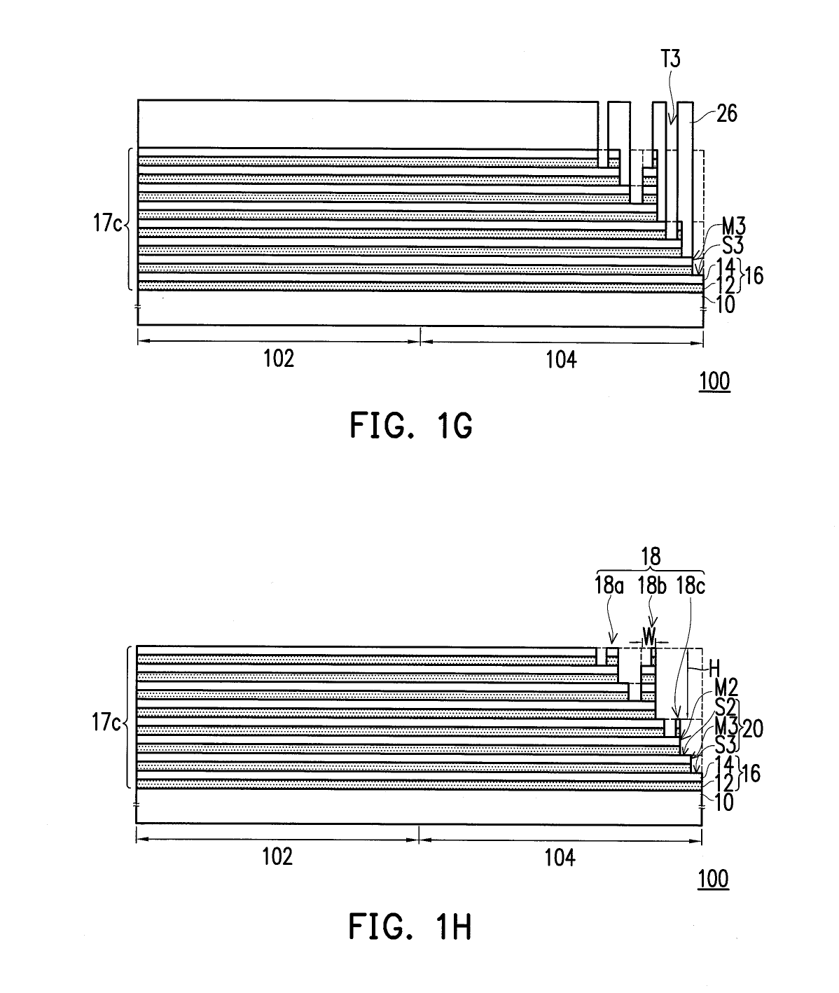

FIG. 1A to FIG. 1H are cross-sectional diagrams illustrating fabrication flows of a semiconductor structure 100 according to an embodiment of the invention.

Referring to FIG. 1A, a substrate 10 is provided. The substrate 10 is, for example, a silicon substrate or a doped polysilicon. The substrate 10 includes a first region 102 and a second region 104 that are located adjacent to each other. In the present embodiment, the following described fabrication method is, for example, performed on the second region 104 of the substrate 10, but the invention is not limited thereto.

Next, a plurality of composite layers 16 is formed on the substrate 10. The method for forming the composite layers 16 is, for example, chemical vapor deposition. The composite layers 16, for example, include two or more than two material layers 12, 14. The material layers 12, 14 may include conductor layers, semiconductor layers, dielectric layers, or a combination thereof. The material layer 12 is, for example, a conductor layer, and the material layer 14 is, for example, a dielectric layer; otherwise, the material layers 12, 14 may both be dielectric layers, such as a nitride layer and an oxide layer.

In one embodiment, the number of the composite layers 16 is, for example, N, wherein N is, for example, an even number, and N≧4. In FIG. 1A, for the purpose of illustration, 8 layers of the composite layers 16 are being drawn for an instance, but the invention is not limited thereto. A person skilled in the art can self-adjust the number of the composite layers 16 according to the practical needs. Multiple composite layers 16 may form a stacked structure 17. The stacked structure 17 has a top-most surface S. Then, a patterned mask layer 22 is formed on the substrate 10. The patterned mask layer 22 cover parts of the stacked structure 17 but exposes parts of the top-most surface S. The method for forming the patterned mask layer 22 is, for example, firstly forming a mask material layer (not shown) via chemical vapor deposition and then performing a photolithoetching step to form the patterned mask layer 22. The patterned mask layer 22 is, for example, a photoresist.

Referring to FIG. 1B, by using the patterned mask layer 22 as a mask, parts of the composite layers 16 exposed by the patterned mask layer 22 are removed, so as to form a stacked structure 17a and a trench T1. The method for removing parts of the composite layers 16 includes performing an etching process to the substrate 10. In one embodiment, when the number of the composite layers 16 is N, then the number of the composite layers 16 that have been partially removed is, for example, N/2 (e.g., 4 layers), but the invention is not limited thereto. The stacked structure 17a, for example, has a sidewall M1 and a surface S1. The trench T1 is, for example, an opening constituted by the sidewall M1 and the surface S1. Afterwards, the patterned mask layer 22 is removed.

Referring to FIG. 1C, a patterned mask layer 24 is formed on the substrate 10. The patterned mask layer 24 covers parts of the top-most surface S of the stacked structure 17a and the sidewall M1 of the trench T1, and covers parts of the surface S1. It is to be noted that, in the present embodiment, the patterned mask layer 24 is required to simultaneously cover the sidewall M1 of the trench T1 and parts of the top-most surface S disposed above the sidewall M1.

Referring to FIG. 1D, by using the patterned mask layer 24 as a mask, an etching process is performed to remove parts of the composite layers 16 exposed by the patterned mask layer 24, so as to form a stacked structure 17b and a trench T2. In this step, the number of the composite layers 16 that have been partially removed is, for example, N/4 (e.g., 2 layers). The stacked structure 17b, for example, has at least one sidewall M2 and at least one surface S2. The trench T2 may be an opening constituted by the sidewall M2 and the surface S2; or, the trench T2 may be a notch constituted by two sidewalls M2 and the surface S2. In one embodiment, a width of the surface S2 is, for example, half of a width of the surface S1, but the invention is not limited thereto.

Referring to FIG. 1E, the patterned mask layer 24 is removed, so as to form at least one staircase structure 20 and at least one composite pillar 18. The staircase structure 20 at least includes the top-most surface S and one of the surface S1 and the surface S2. Moreover, the staircase structure 20 at least include one of the sidewall M1 and the sidewall M2. For instance, the staircase structure 20 may be constituted by the top-most surface S, the sidewall M2 and the surface S2; or, the staircase structure 20 may also be constituted by the surface S1, the sidewall M2 and the surface S2.

The composite pillar 18 is disposed on the surface S2 of the staircase structure 20. In the present embodiment, a sidewall of the composite pillar 18 includes a portion of the sidewall of trench T1 or a portion of a sidewall of the trench T2. For instance, the sidewall of the composite pillar 18 includes a portion of the sidewall M1. That is, the composite pillar 18 is substantially disposed at an edge region of the surface S2, as shown in FIG. 1E. A width W of the composite pillar 18 is not particularly limited. For instance, the width W of the composite pillar 18 complies with a condition of not causing defects in the semiconductor structure 100 by making the composite pillar 18 being susceptible to breaking. In one embodiment, the width W of the composite pillar 18 is, for example, greater than 0.15 microns. A height H of the composite pillar 18 is, for example, greater than a height of the composite layers 16.

In one embodiment, when the number of the composite layers 16 is N, then the number of the composite pillars 18 is X≦N/2−1 pillars, wherein N≧4 and N is an even number, and X≧1 and X is an integer. For instance, when the number of the composite layers 16 is respectively, 8, 16 and 32, then the number X of the composite pillar 18 may at least be 3, 7 and 15, respectively. In addition, it is to be noted that, since the composite pillar 18 is substantially disposed on the edge region of the surface S2, it may provide a process margin of an overlay alignment in the lithography process.

Referring to FIG. 1F, next, a patterned mask layer 26 is formed on the substrate 10. The patterned mask layer 26 covers the sidewall M1, sidewall M2 and parts of the top-most surface S of the stacked structure 17b, parts of the surface S1 and parts of the surface S2. It is to be noted that, in the present embodiment, the patterned mask layer 26 is required to simultaneously cover the sidewall M1 of the trench T1, parts of the top-most surface S disposed above the sidewall M1, the sidewall M2 of the trench T2, parts of the top-most surface S disposed above the sidewall M2, and parts of the surface S1.

Referring to FIG. 1G, by using the patterned mask layer 26 as a mask, the etching process is performed to remove parts of the composite layers 16 exposed by the patterned mask layer 26, so as to form a stacked structure 17c and a trench T3. In this step, the number of the composite layers 16 that have been partially removed is, for example, N/8 (e.g., 1 layer). The stacked structure 17c, for example, has at least one sidewall M3 and at least one surface S3. In one embodiment, a width of the surface S3 is half of the width of the surface S2, but the invention is not limited thereto.

Referring to FIG. 1H, the patterned mask layer 26 is removed, so as to form at least one staircase structure 20 and at least one composite pillar 18. In the present embodiment, one of the staircase structures 20 is, for example, constituted by the surface S2, the sidewall M3 and the surface S3. The width W and the height H of the composite pillar 18 may be the same or different. In the present embodiment, the composite pillar 18, for example, includes composite pillars 18a, 18b, 18c, which have different widths W and heights H. Moreover, the sidewall of the composite pillar 18 may include a portion of the sidewall M1, a portion of the sidewall M2 or a portion of the sidewall M3.

The subsequent method for fabricating the semiconductor structure 100 includes forming a contact window (not shown) on each surface of the stacked structure 17c (e.g., the top-most surface S, the surface S1, the surface S2 and the surface S3), so that components (e.g., memory cells) disposed at each of the composite layers 16 may be electrically connected with other components (e.g., word-line, bit-line, and etc). The subsequent method for forming the contact windows and the other components should be familiar by those skilled in the art, and thus details regarding thereof will not be elaborated herein.

It is to be noted that, the aforementioned method for fabricating the semiconductor structure 100 includes performing a patterning process to the composite layers 16 for m times, wherein m is a positive integer greater than 1. When 2, a m^{th} patterned mask layer is formed, and the m^{th} patterned mask, for example, covers a sidewall of a (m−1)^{th} trench formed by the (m−1)^{th} time of the patterning process. For instance, as shown in FIG. 1C, the patterned mask layer 24 covers the sidewall M1 of the trench T1.

In addition, for each time of performing the patterning process, at least one trench (e.g., trench T1) is formed, and the trench may be constituted by at least one sidewall (e.g., the sidewall M1) and at least one surface (e.g., the surface S1). That is, at least one sidewall and at least one surface would be formed with each performance of the patterning process. In one embodiment, a width of the surface formed by each patterning process is, for example, half of a width of the surface formed by the previous patterning process. For instance, the width of the surface S2 is, for example, half of the width of the surface S1. Nevertheless, in other embodiments, the widths of the surfaces S2 of the trenches may be different from each other.

In the present embodiment, when the composite layers are N layers, N 4 and N is an even number, when performing the patterning process to the composite layers for m times, a number L of the composite layers being removed each time satisfies the condition of L=N/r, until L=1. For instance, when the composite layers are 8 layers, and when performing the patterning process to the composite layers for 3 times, the number L of the composite layers being removed during the 1^{st} time of the patterning process is 4; the number L of the composite layers being removed during the 2^{nd} time of the patterning process is 2; and the number L of the composite layers being removed during the 3^{rd} time of the patterning process is 1. That is, the number of the composite layers 16 being removed during each time of the patterning process is, for example, half of the number of the composite layers 16 being removed during the previous patterning process.

As a result, through forming the patterned mask layers on the sidewalls of the trenches and in combination with the patterning processes, when the composite layers 16 are N layers, then the number of photomasks required for patterning the composite layers 16 is at least n, wherein N≦2ⁿ, N≧4 and N is an even number, n≧1 and n is an integer. For instance, in the present embodiment, when the composite layers 16 are 8 layers, then the number of photomasks required for patterning the composite layers 16 is at least 3. Namely, in order to form the semiconductor structure 100 as shown in FIG. 1H, it requires performing the patterning process for at least 3 times, and as compared to the conventional art, which requires performing the patterning process for 8 times, the number of times for performing the patterning process is greatly reduced.

According to the aforementioned implementations, the semiconductor structure 100 of the invention can be fabricated. Next, in the following descriptions, structures of the semiconductor structure 100 according to an embodiment of the invention would be provided with reference to FIG. 1H.

Firstly, referring to FIG. 1H again, the semiconductor structure 100 includes the substrate 10, the plurality of composite layers 16 and the at least one composite pillar 18. The substrate 10 includes the first region 102 and the second region 104. The plurality of composite layers 16 is disposed on the substrate 10, and may form the stacked structure 17c. The composite layers 16 include the material layers 12, 14. Each of the composite layers 16 includes at least one exposed surface and at least one sidewall. The exposed surfaces may include the top-most surface S, the surface S1, the surface S2 and the surface S3. The sidewalls may include the sidewall M1, the sidewall M2 and the sidewall M3. The exposed surfaces and the sidewalls may form the at least one staircase structure 20. In other words, the stacked structure 17c, for example, include a plurality of staircase structures 20. The composite pillars 18 are disposed on the exposed surfaces of the composite layers 16, and the sidewalls of the composite pillars 18 are, for example, connected with the sidewalls of the composite layers 16. That is, the composite pillars 18 are substantially disposed at the edge regions of the exposed surfaces of the composite layers 16. Materials, forming methods and effects of the various components in the semiconductor structure 100 are already provided in the above embodiments, and thus will not be repeated herein.

It is to be noted that, since the semiconductor structure provided by the invention has the staircase structure and the composite pillar, in addition to enabling the components at each of the composite layers to connect with other components easily, it may further provide the process margin of the overlay alignment in the lithography process of forming the staircase structure.

In addition, the method for fabricating the semiconductor structure 100 is, for example, to form the staircase structure 20 and the composite pillar 18 on the second region 104 of the substrate 10, but the invention is not limited thereto. In other embodiments, the staircase structure 20 and the composite pillar 18 may also be formed on the first region 102 of the substrate 10, as described in below.

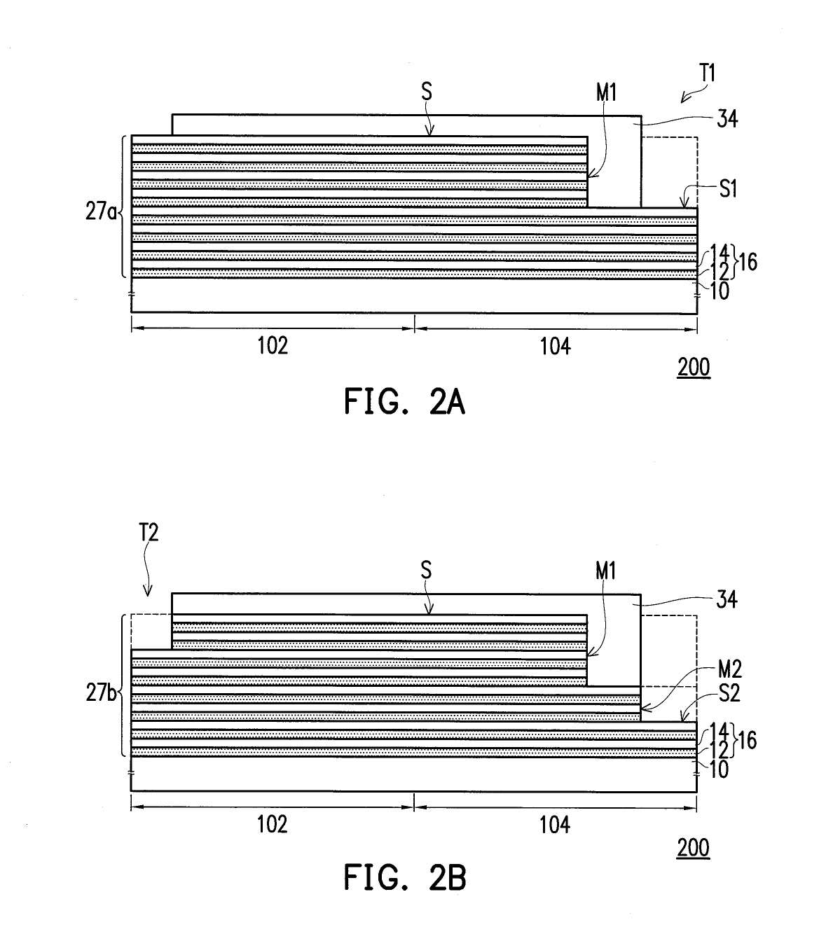

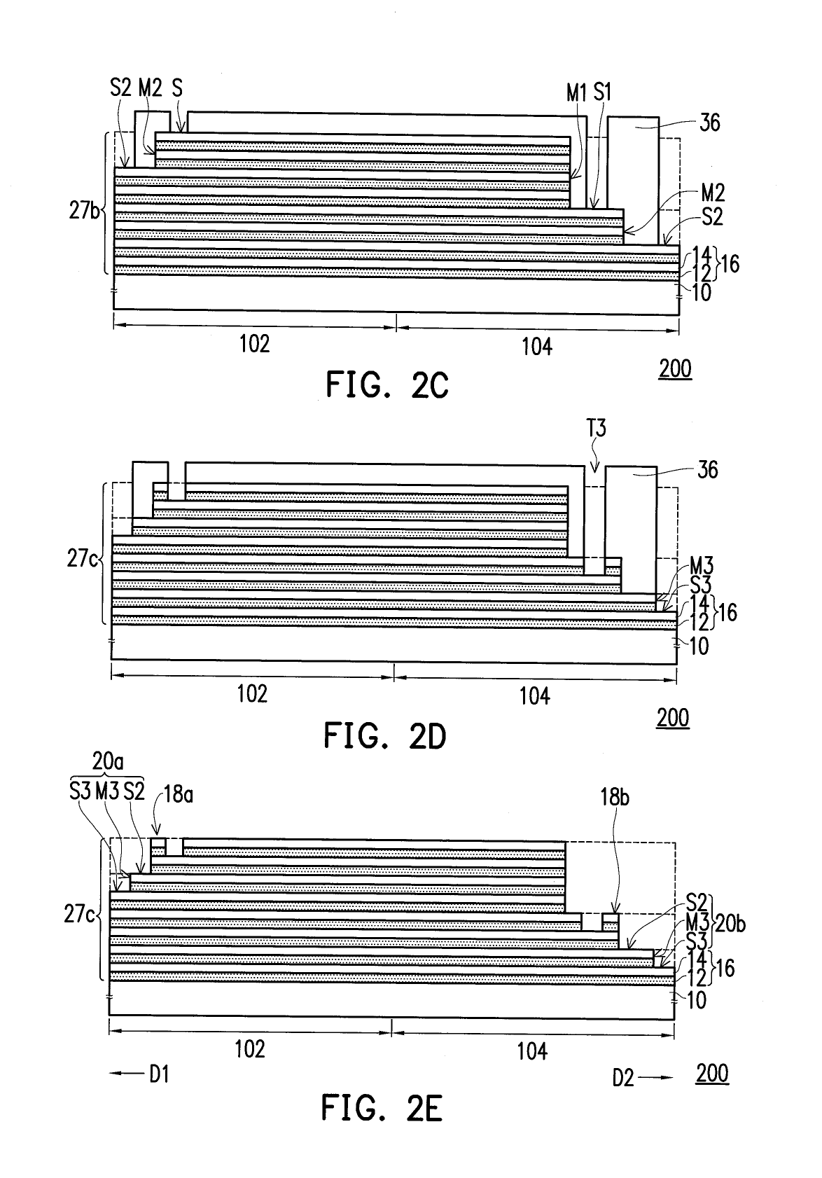

FIG. 2A to FIG. 2E are cross-sectional diagrams illustrating fabrication flows of a semiconductor structure 200 according to another embodiment of the invention.

Referring to FIG. 2A, after forming a stacked structure 27a and a trench T1 on the substrate 10, a patterned mask layer 34 is further formed on the stacked structure 27a. The stacked structure 27a, for example, has a sidewall M1 and a surface S1 disposed at the second region 104 of the substrate 10. It is to be noted that, the patterned mask layer 34, in addition to covering a portion of the sidewall M1 of the trench T1 and parts of the surface S1, further covers parts of the top-most surface S disposed above the sidewall M1, so as to expose parts of the top-most surface S on the first region 102.

Referring to FIG. 2B, next, by using the patterned mask layer 34 as a mask, an etching process is performed to remove parts of the composite layers 16 exposed by the patterned mask layer 34, so as to form a stacked structure 27b and a trench T2. The stacked structure 27b, for example, has at least one sidewall M2 and at least one surface S2, wherein the sidewall M2 and the surface S2 may be disposed at the first region 102 or the second region 104 of the substrate 10. In the present embodiment, the first region 102 and the second region 104 respectively have the sidewall M2 and the surface S2. The trench T2 is, for example, an opening constituted by the sidewall M2 and the surface S2.

Referring to FIG. 2C, a patterned mask layer 36 is formed on the substrate 10. The patterned mask layer 36 covers the sidewall M1 of the trench T1, the sidewall M2 of the trench T2, parts of the surface S1, and parts of the surface S2, so as to expose parts of the top-most surface S and parts of the surfaces S2 of the first region 102 and parts of the surface S1 and parts of the surface S2 of the second region 104.

Referring to FIG. 2D, by using the patterned mask layer 36 as a mask, an etching process is performed to remove parts of the composite layers 36 exposed by the patterned mask layer 36, so as to form a stacked structure 27c and a trench T3. The stacked structure 27c, for example, has at least one sidewall M3 and at least one surface S3, wherein the sidewall M3 and the surface S3 respectively disposed at the first region 102 and the second region 104 of the substrate 10. The trench T3 may be an opening constituted by the sidewall M3 and the surface S3; or, the trench T3 may be a notch constituted by two sidewalls M3 and the surface S3.

Referring to FIG. 2E, the patterned mask layer 36 is removed to form at least one staircase structure 20a, 20b and at least one composite pillar 18a, 18b on the substrate 10. In the present embodiment, the staircase structures 20a, 20b are respectively disposed at the first region 102 and the second region 104 of the substrate 10, and heights of the staircase structures 20a, 20b decrease respectively along opposite directions. For instance, the height of the staircase structure 20a decreases along a first direction D1, and the height of the staircase structure 20b decreases along a second direction D2. The first direction D1 is opposite to the second direction D2. The composite pillars 18a, 18b are, for example, respectively disposed at the at least one exposed surfaces (e.g., the surfaces S3) in the first region 102 and the second region 104 of the substrate 10.

It is to be noted that, in the semiconductor structure 200, since the first region 102 and the second region 104 of the substrate 10 respectively have the staircase structures 20a, 20b and the composite pillars 18a, 18b, as a result, in addition to enabling the components disposed at each of the composite layers 16 to connect with other components easily, goals of having high-density and high-performance within a limited unit area may also be achieved.

In addition, it is to be noted that the semiconductor structures 100, 200 described in the above are merely provided as examples for the purpose of illustration, and thus the invention is not limited thereto. In other words, other semiconductor structures may also be formed using the method for fabricating the semiconductor structure provided by the invention. When the number of the composite layers is, for example, N, and the number of photomasks required for patterning the composite layers is at least n, wherein N≦2ⁿ, then 2ⁿ⁻¹ types of different semiconductor structures can be formed, wherein N is, for example, an even number and N≧4, and n≧1 and n is an integer. For instance, when the numbers of the composite layers are respectively 8, 16 and 32, then 4, 8 and 16 types of different semiconductor structures can respectively be formed through using the fabrication method provided by the invention.

Taking 8 composite layers as an instance, Table 1 lists the types of the final semiconductor structures being formed when selectively performing the patterning process to the composite layers on the first region 102 or the second region 104 of the substrate 10 to expose new sidewalls and new surfaces, and the numbers and heights of the composite pillars included in the different semiconductor structures. In Table 1, I presents the first region, II represents the second region, and the height of the composite pillar is presented by the number of the composite layers.

TABLE 1

| Type | 1 | 2 | 3 | 4 |
|---|---|---|---|---|
| First patterning | II | II | II | II |
| Second patterning | II | II | I | I |
| Third patterning | II | I | II | I |
| Number of composite pillar | 3 | 2 | 2 | 2 |
| Height of composite pillar | 3 | 3 | 1 | 1 |

In Table 1, as previously described, the number of the composite layers is 8, and thus the number of the composite pillars capable of being formed is at most 3. For instance, the semiconductor structure of Type 1 is, for example, as shown in FIG. 1H, such that the 3 times of the patterning process are all performed on the second regions 104 of the substrate 10, so as to form the composite pillars 18a, 18b, 18c. Further, the height H of the composite pillars 18a, 18b, 18c can be 3 layers or the height of 1 composite layer.

Moreover, the semiconductor structure of Type 4 is, for example, as shown in FIG. 2E, which includes respectively performing the patterning process on the first region 102 and the second region 104 of the substrate 10 to form the staircase structures 20a, 20b and the composite pillars 18a, 18b on the first region 102 and the second region 104, wherein the height H in the composite pillars 18a, 18b is, for example, the height of 1 composite layer.

However, in other embodiments, even if the patterning process is respectively performed on the first region 102 and the second region 104 of the substrate 10, the resulting staircase structure 20 or composite pillar 18 may also be merely disposed on the first region 102 or the second region 104, as described in the following.

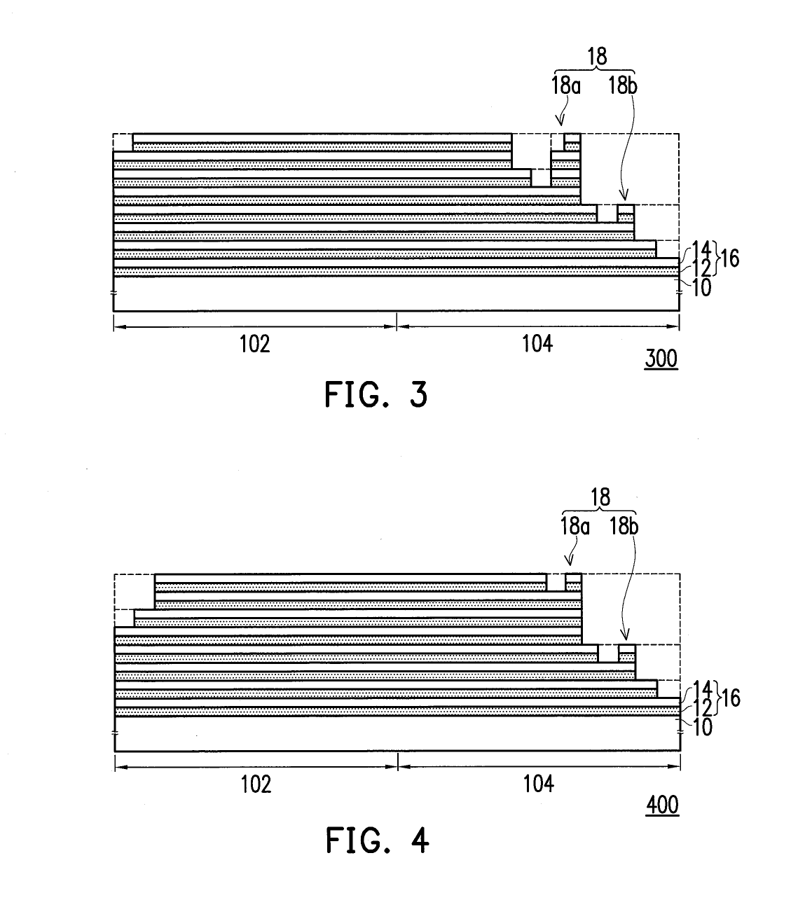

FIG. 3 to FIG. 4 are cross-sectional diagrams respectively illustrating a semiconductor structure according to yet another embodiment of the invention.

Referring to Table 1, FIG. 3 and FIG. 4 at the same time, in Table 1, Type 2 is, for example, represented by a semiconductor structure 300 shown in FIG. 3, and Type 3 is, for example, represented by a semiconductor structure 400 shown in FIG. 4. The number of the composite pillars 18 in both the semiconductor structures 300, 400 is 2, but since the steps of the patterning process are different, the shapes and the heights of the resulting composite pillars 18 are also different. The semiconductor structures 100, 200, 300, 400 described in the above are merely provided as examples for the purpose of illustration, and thus the invention is not limited thereto. A person skilled in the art can self-adjust the shape, the number, the width and the height of the composite pillars 18 and the locations of the staircase structures 20 according to the practical needs.

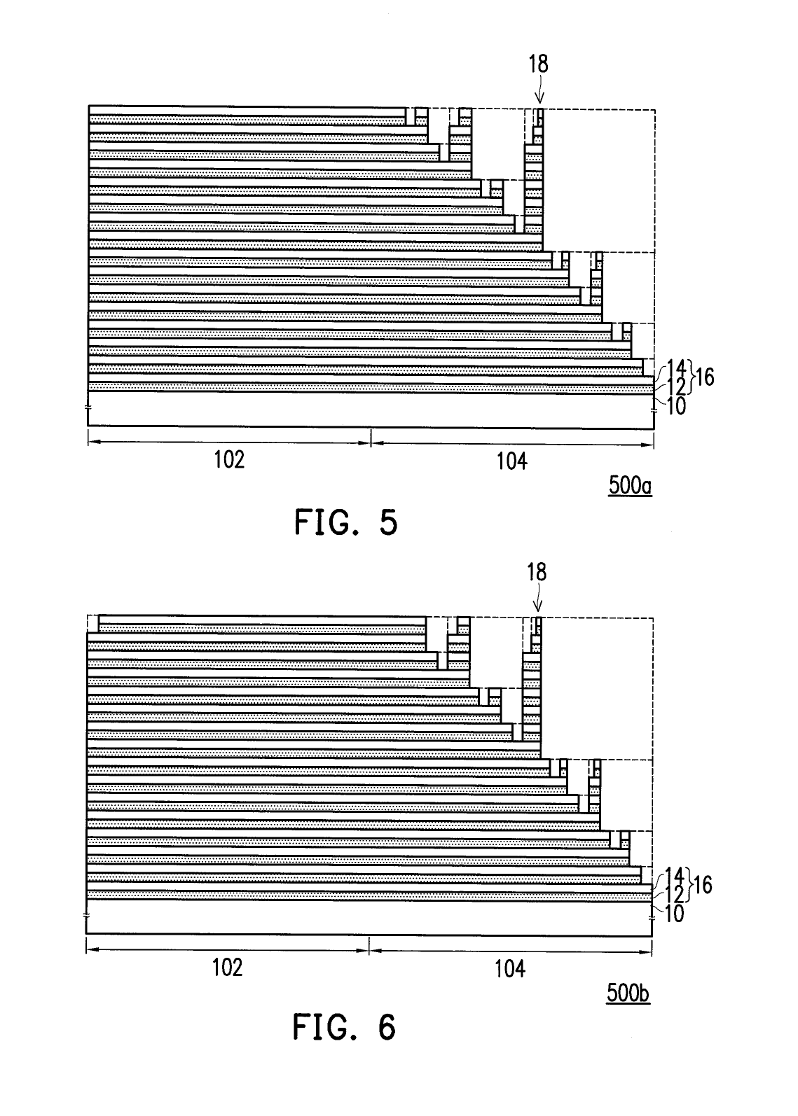

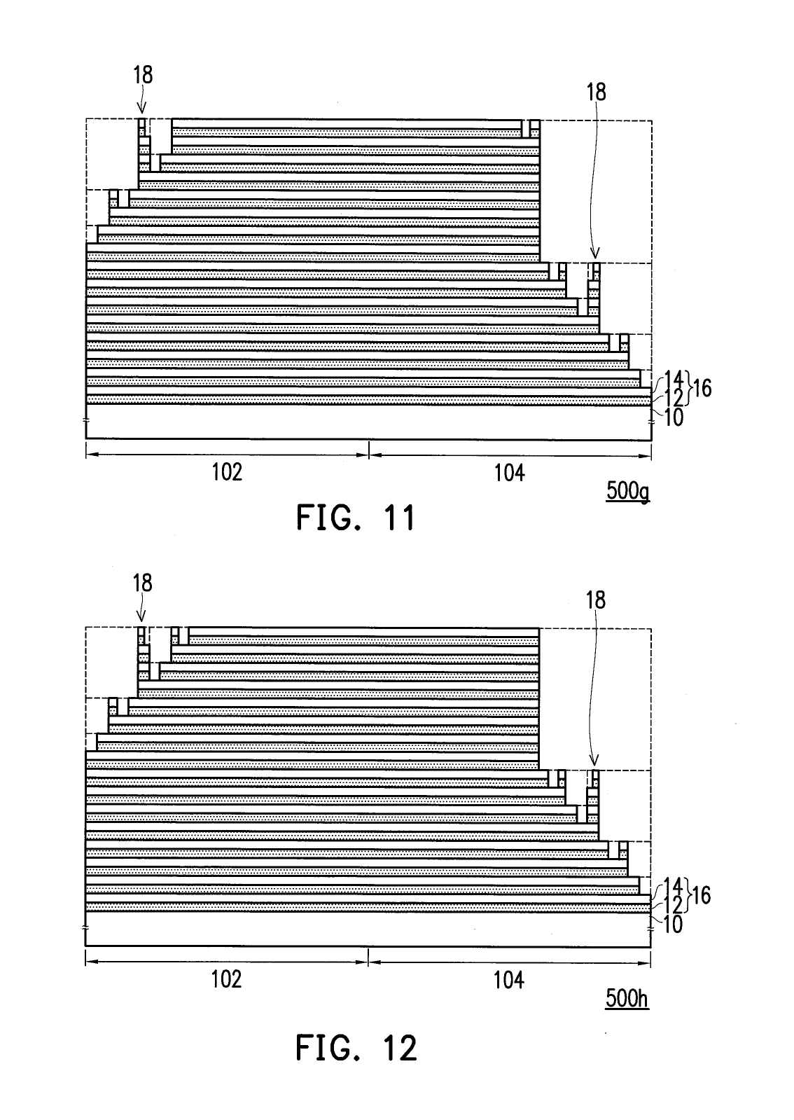

FIG. 5 to FIG. 12 are cross-sectional diagrams respectively illustrating a semiconductor structure according to still another embodiment of the invention. In the present embodiment, taking 16 composite layers for an example, the types of the final semiconductor structures being formed are listed in Table 2 below. In Table 2, I represents the first region, II represents the second region, and the height of the composite pillar is represented by the number of the composite layers.

TABLE 2

| Type | 1 | 2 | 3 | 4 | 5 | 6 | 7 | 8 |
|---|---|---|---|---|---|---|---|---|
| First patterning | II | II | II | II | II | II | II | II |
| Second patterning | II | II | II | II | I | I | I | I |
| Third patterning | II | II | I | I | II | II | I | I |
| Fourth patterning | II | I | II | I | II | I | II | I |
| Number of composite pillar | 7 | 6 | 6 | 6 | 6 | 6 | 6 | 6 |
| Height of composite pillar | 7 | 7 | 7 | 7 | 3 | 3 | 3 | 3 |

Type 1 to Type 8 in Table 2 are respectively semiconductor structures 500a-500h as shown in FIG. 6 to FIG. 12. It is to be noted that, as previously described, when the number N of the composite layers 16 is 16, then the number X of the composite pillars 18 is at most 7, and the number n of the photomasks required for forming the semiconductor structures 500a-500h is at least 4; namely, it requires to perform the patterning process for 4 times. As a result, 8 different types of the semiconductor structures may be formed, as shown in FIG. 6 to FIG. 12.

Referring to Table 2 and FIG. 5 at the same time, the semiconductor structure 500a of Type 1 is, for example, being performed with the patterning process on the second region 104 of the substrate 10 for 4 times, so as to form 7 composite pillars 18. Moreover, the height of the composite pillars 18 can at most be a total height of 7 composite layers 16.

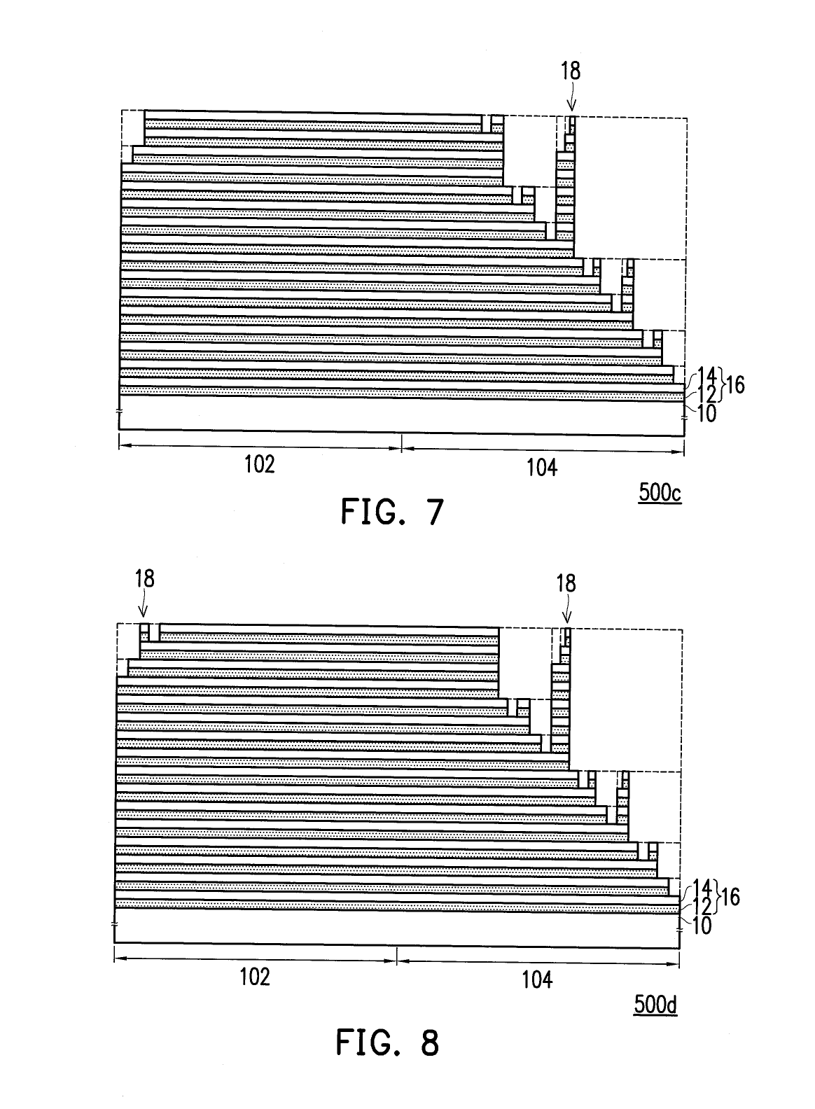

Referring to Table 2, FIG. 6, FIG. 7 and FIG. 8 at the same time, the semiconductor structures 500b, 500c, 500d of Type 2 to Type 4 are, for example, being performed with the patterning process on the first region 102 and the second region 104 of the substrate 10, respectively, so as to form 6 composite pillars 18. Moreover, the height H of the composite pillars 18 can at least be a total height of 7 composite layers 16.

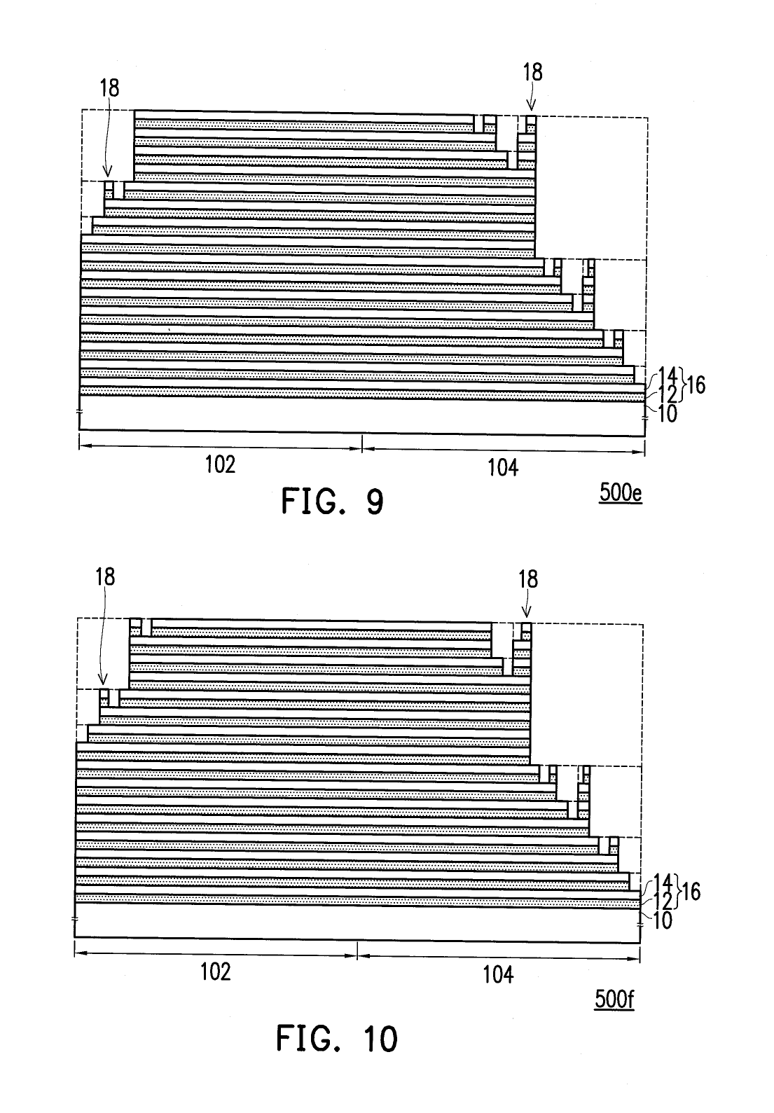

Referring to Table 2 and FIG. 9 to FIG. 12 at the same time, the semiconductor structures 500e, 500f, 500g, 500h of Type 5 to Type 8 are, for example, being performed with the patterning process on the first region 102 and the second region 104 of the substrate 10, respectively, so as to form 6 composite pillars 18. Moreover, the height H of the composite pillars 18 can at least be a total height of 3 composite layers 16.

In summary, in the method for fabricating the semiconductor structure of the invention, by covering the patterned mask layers on the sidewalls of the trenches and the surfaces of the composite layers, it is facilitative in simultaneously forming the staircase structures and the composite pillars during the subsequent processes. In addition, the number of the composite layers being removed during each time of the patterning process is half of the previous time. Consequently, as compared to the conventional fabrication process, when fabricating staircase structures with same number of layers, the number of times for performing the patterning process can be greatly reduced, thereby achieving goals of lowering the manufacturing costs and enhancing the productivity. Moreover, the aforementioned fabrication method can form a semiconductor structure which simultaneously has the staircase structure and the composite pillar, and thus in addition to enabling the components disposed at each of the composite layers to connect with other components easily, may further provide the process margin of the overlay alignment overlay alignment in the lithography process of forming the staircase structure.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A semiconductor structure, comprising:
a substrate, comprising a first region and a second region;
a plurality of composite layers, disposed on the substrate, each of the composite layers comprising at least one exposed surface and at least one sidewall, the exposed surfaces and the sidewalls forming at least one staircase structure; and
at least one composite pillar, disposed on the at least one exposed surface of each of the composite layers.

2. The semiconductor structure as recited in claim 1, wherein a height of the at least one composite pillar is greater than or equal to a height of each of the composite layers.

3. The semiconductor structure as recited in claim 1, wherein the composite layers are N layers, and the number of the at least one composite pillar is X, wherein X≦N/2−1, N≧4 and N is an even number, and X≧1 and X is an integer.

4. The semiconductor structure as recited in claim 1, wherein the at least one staircase structure is more than one staircase structures, the staircase structures are respectively disposed at the first region and the second region of the substrate, and heights of each staircase structure decreases respectively along opposite directions.

5. The semiconductor structure as recited in claim 1, wherein the at least one composite pillar is disposed on the at least one exposed surface of each of the composite layers at the first region or the second region of the substrate.

6. The semiconductor structure as recited in claim 1, wherein a sidewall of the at least one composite pillar is connected with one of the at least one sidewall of each of the composite layers.

7. The semiconductor structure as recited in claim 1, wherein each of the composite layers at least comprises two material layers, and the material layers comprises conductor layers, semiconductor layers, dielectric layers or a combination thereof.

8. A method for fabricating the semiconductor structure, comprising:
providing a substrate, the substrate comprising a first region and a second region;
forming a plurality of composite layers on the substrate; and
performing a patterning process to the composite layers for m times, in which m is a positive integer greater than 1, so as to form at least one staircase structure and at least one composite pillar on the substrate,
wherein performing the patterning process for m 2 times comprise:
forming a m^{th} patterned mask layer, the m^{th} patterned mask layer covering a sidewall of at least one (m−1)^{th} trench formed by the (m−1)^{th} time of the patterning process;
removing parts of the composite layers through using the m^{th} patterned mask layer as a mask, so as to form at least one m^{th} trench; and
removing the m^{th} patterned mask layer,
wherein the at least one staircase structure comprises at least one exposed surface, and the at least one composite pillar is disposed on the at least one exposed surface of the at least one staircase structure.

9. The method for fabricating the semiconductor structure as recited in claim 8, wherein the composite layers are N layers, N≧4 and N is an even number, wherein when performing the patterning process to the composite layers for m times, a number L of the composite layers being removed satisfies the following formula, until L=1.
L=N/2^{m}.

10. The method for fabricating the semiconductor structure as recited in claim 8, wherein the method for performing the patterning process to the composite layers for m times comprises:
forming a 1^{st} patterned mask layer on the substrate, the 1^{st} patterned mask layer covers parts of the composite layers;
removing parts of the composite layers exposed by the 1^{st} patterned mask layer, so as to form a 1^{st} trench;
removing the 1^{st} patterned mask layer;
forming a 2^{nd} patterned mask layer on the substrate, the 2^{nd} patterned mask layer covers a sidewall of the 1^{st} trench;
removing parts of the composite layers exposed by the 2^{nd} mask layer, so as to form at least one 2^{nd} trench; and
removing the 2^{nd} patterned mask layer, so as to form the at least one staircase structure and the at least one composite pillar on the substrate.

11. The method for fabricating the semiconductor structure as recited in claim 10, wherein the composite layers have a top-most surface, and the 2^{nd} patterned mask layer simultaneously covers the sidewall of the 1^{st} trench and parts of the top-most surface disposed above the sidewall of the 1^{st} trench.

12. The method for fabricating the semiconductor structure as recited in claim 8, wherein a sidewall of the at least one composite pillar comprises a portion of the sidewall of the at least one (m−1)^{th} trench or a portion of a sidewall of the at least one m^{th} trench.

13. The method for fabricating the semiconductor structure as recited in claim 8, wherein the method for forming the at least one staircase structure on the substrate comprises respectively forming the at least one staircase structure on the first region and the second region of the substrate, and heights of the staircase structures decrease respectively along opposite directions.

14. The method for fabricating the semiconductor structure as recited in claim 8, further comprising respectively forming the at least one composite pillar on the first region and the second region of the substrate.

15. The method for fabricating the semiconductor structure as recited in claim 8, wherein a height of the at least one composite pillar is greater than or equal to a height of each of the composite layers.

16. The method for fabricating the semiconductor structure as recited in claim 8, wherein the composite layers are N layers, and the number of the at least one composite pillar is X, wherein X≦N/2−1, N≧4 and N is an even number, and X≧1 and X is an integer.
